(19) United States
(12) Patent Application Publication
(10) Pub. No.: US 2026/0341317 A1
(43) Pub. Date: Oct. 29, 2026

(54) MEMORY DEVICE AND MANUFACTURING METHOD OF THE MEMORY DEVICE

(71) Applicant: SK hynix Inc., Icheon-si Gyeonggi-do (KR)

(72) Inventors: Sang Min LEE, Icheon-si Gyeonggi-do (KR); Dong Ik LEE, Icheon-si Gyeonggi-do (KR)

(73) Assignee: SK hynix Inc., Icheon-si Gyeonggi-do (KR)

(21) Appl. No.: 19/367,485

(22) Filed: Oct. 23, 2025

(30) Foreign Application Priority Data
Apr. 24, 2025 (KR) 10-2025-0053621

(51) Int. Cl. G11C 5/06; H10B 43/10; H10B 43/35

(52) U.S. Cl. CPC G11C 5/063; H10B 43/10; H10B 43/35

(57) ABSTRACT

A memory device includes a stack including conductive layers and interlayer insulating layers stacked alternately with each other, a cell plug extending through the stack, and a contact in electrical contact with at least one of the conductive layers. The memory device also includes a spacer between the contact and the stack. The memory device further includes a support structure extending through the stack. The support structure comprises a first portion and a second portion under the first portion, the second portion having a greater width than the first portion. An interface between the first portion and the second portion is located at a different level from interfaces between the conductive layers and the interlayer insulating layers.

### CROSS-REFERENCE TO RELATED APPLICATION

The present application claims priority under 35 U.S.C. § 119 (a) to Korean patent application number 10-2025-0053621 filed on Apr. 24, 2025, in the Korean Intellectual Property Office, the entire contents of which application is incorporated herein by reference.

### BACKGROUND

### 1. Technical Field

Some embodiments of the present disclosure relate to a memory device and a manufacturing method thereof, and more particularly, to a memory device including a memory block having a three-dimensional structure and a method of manufacturing the memory device.

### 2. Related Art

A memory device may include a non-volatile memory device in which stored data remains intact even when supplied power is discontinued. The non-volatile memory device may be categorized as a two-dimensional structure or a three-dimensional structure, depending on how its memory cells are arranged. The memory cells of the non-volatile memory device having the two-dimensional structure may be arranged in a single layer on a substrate, and the memory cells of the non-volatile memory device having the three-dimensional structure may be stacked in a vertical direction on the substrate. The integration density of the non-volatile memory device having the three-dimensional structure is higher than that of the non-volatile memory device having the two-dimensional structure. Thus, electronic devices using non-volatile memory devices having a three-dimensional structure have recently been increasing.

A non-volatile memory device having a three-dimensional structure includes layers that are stacked in a vertical direction. Support structures that penetrate the stacked layers are formed to support the stacked layers.

### SUMMARY

According to an embodiment, a memory device may include a stack including conductive layers and interlayer insulating layers stacked alternately with each other, a cell plug extending through the stack, a contact in electrical contact with at least one of the conductive layers, a spacer between the contact and the stack, and a support structure extending through the stack. The support structure includes a first portion and a second portion under the first portion, the second portion having a greater width than the first portion. An interface between the first portion and the second portion is located at a different level from interfaces between the conductive layers and the interlayer insulating layers.

According to an embodiment, a method of manufacturing a memory device may include forming a preliminary stack including sacrificial layers and interlayer insulating layers stacked alternately with each other, forming an opening through the preliminary stack, forming a barrier layer on a side surface of the preliminary stack exposed through the opening, forming a cover layer on a portion of the barrier layer leaving a remaining portion of the barrier layer exposed, forming a barrier pattern exposing a portion of the side surface of the preliminary stack by removing the exposed portion of the barrier layer, forming an expanded opening relative to the opening by etching the portion of the side surface of the preliminary stack exposed by the barrier pattern, and forming a support structure in the expanded opening.

According to an embodiment, a memory device may include a stack including conductive layers and interlayer insulating layers stacked alternately with each other, contacts in electrical contact with the conductive layers, spacers between the contacts and the stack, and first support structures and second support structures extending through the stack. Each of the first support structures comprises a first portion and a second portion under the first portion, the second portion having a width greater than the first portion. A width of each of the second support structures is constant or is reduced in a linear taper from the top to the bottom of the second support structure.

### BRIEF DESCRIPTION OF THE DRAWINGS

FIG. 1 is a diagram illustrating a memory device according to an embodiment of the present disclosure;

FIG. 2 is a diagram illustrating a memory device according to an embodiment of the present disclosure;

FIGS. 3A to 3C are diagrams illustrating a memory device including support structures according to an embodiment of the present disclosure;

FIGS. 4A to 4K are diagrams illustrating a method of manufacturing a memory device including a support structure according to an embodiment of the present disclosure;

FIG. 5 is a diagram illustrating a memory device including support structures extending through a source structure according to an embodiment of the present disclosure;

FIGS. 6A to 6C are diagrams illustrating a memory device including first and second support structures according to some embodiments of the present disclosure;

FIGS. 7A to 7C are diagrams illustrating the positional relationship of a support structure and a contact according to an embodiment of the present disclosure;

FIG. 8 is a diagram illustrating a memory card system to which a memory device in accordance with an embodiment of the present disclosure is applied; and

FIG. 9 is a diagram illustrating a solid-state drive (SSD) system to which a memory device in accordance with an embodiment of the present disclosure is applied.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, some embodiments of the present disclosure are described in detail with reference to the accompanying drawings for those skilled in the art to be able to implement the technical spirit of the present disclosure. An embodiment directed to a memory device and a manufacturing method thereof may reduce defects in a stack by improving the shape of a support structure.

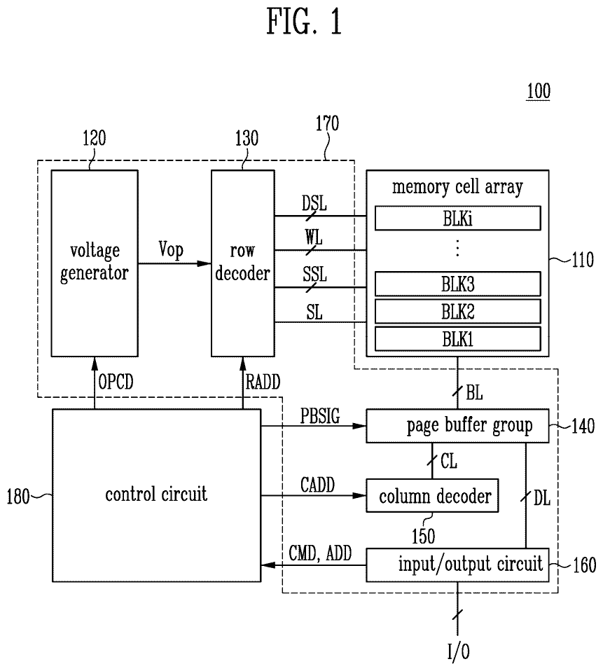

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells capable of storing data. Drain select lines DSL, word lines WL, source select lines SSL, and a source line SL may be coupled to each of the first to ith memory blocks BLK1 to BLKi, and bit lines BL may be commonly coupled to the first to ith memory blocks BLK1 to BLKi.

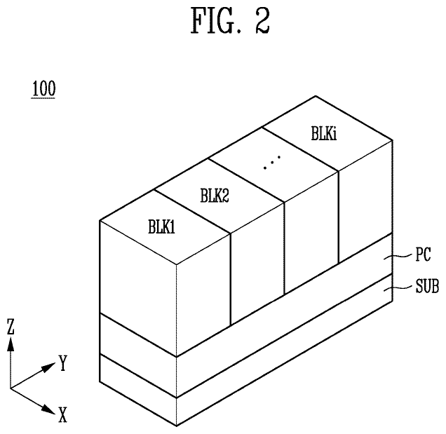

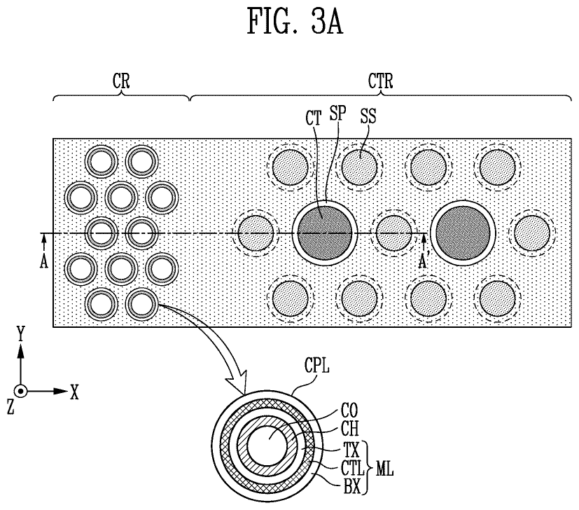

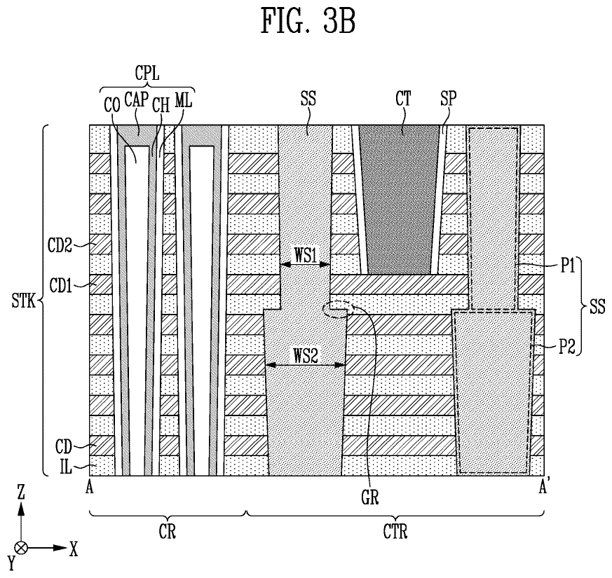

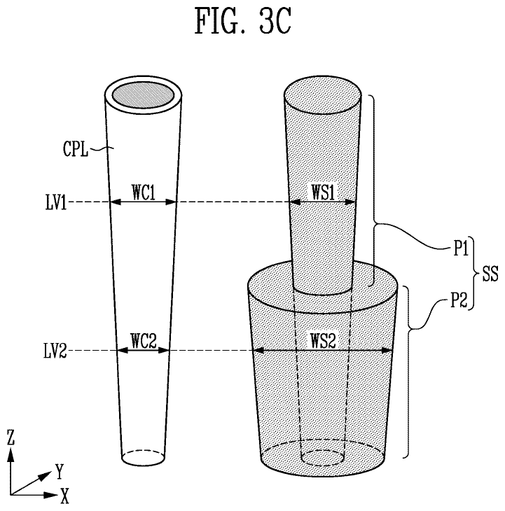

The first to ith memory blocks BLK1 to BLKi may be formed to have a three-dimensional structure. These memory blocks having a three-dimensional structure may include memory cells stacked in a vertical direction from the substrate. The configuration of the first to ith memory blocks BLK1 to BLKi with a three-dimensional structure is described below with reference to FIGS. 2, 3A, and 3B.

The memory cells may store one bit of data, or two or more bits of data, depending on a programing method. For example, a method in which one bit of data is stored in one memory cell is referred to as a single-level cell method, and a method in which two bits of data are stored is referred to as a multi-level cell method. A method in which three bits of data are stored in a single memory cell is referred to as a triple-level cell method, and a method in which four bits of data are stored in a single memory cell is referred to as a quad-level cell method. In addition, five or more bits of data may be stored in a single memory cell.

The peripheral circuit 170 may perform a program operation for storing data in the memory cell array 110, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operation voltages Vop for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operation voltages Vop generated by the voltage generator 120 may be applied to the drain select lines DSL, the word lines WL, the source select lines SSL, the and the source line SL of a selected memory block via the row decoder 130.

Program voltages may be applied to a selected word line of the word lines WL during a program operation, and they may be applied to increase threshold voltages of memory cells coupled to the selected word line. Turn-on voltages may be applied to the drain select lines DSL or the source select lines SSL, and they may be applied to turn on drain select transistors or source select transistors. Turn-off voltages may be applied to the drain select lines DSL or the source select lines SSL, and they may be applied to turn off the drain select transistors or the source select transistors. For example, a turn-off voltage may be set to 0 V. Precharge voltages may be higher than 0 V, which may be applied to bit lines during a read operation. Verify voltages may be applied during a verify operation to determine whether threshold voltages of selected memory cells have risen to a target level. The verify voltages may be set at various levels based on the target level and may be applied to the selected word line.

Read voltages may be applied to the selected word line during a read operation of the selected memory cells. For example, the read voltages may be set to various levels depending on how the selected memory cells are programmed. Pass voltages may be applied to unselected word lines of the word lines WL during a program or read operation, and they may be applied to turn on memory cells coupled to the unselected word lines. Erase voltages may be applied to the source line SL, and they may be applied during an erase operation to erase the memory cells included in the selected memory block.

The row decoder 130 may transfer the operation voltages Vop to the drain select lines DSL, the word lines WL, the source select lines SSL, and the source line SL coupled to selected memory block according to a row address RADD. For example, the row decoder 130 may be coupled to the voltage generator 120 via global lines, and to the first to ith memory blocks BLK1 to BLKi through the drain select lines DSL, the word lines WL, the source select lines SSL, and the source line SL.

The page buffer group 140 may include page buffers (not shown) coupled to the first to ith memory blocks BLK1 to BLKi, respectively. More specifically, the page buffers may be coupled to the first to ith memory blocks BLK1 to BLKi, respectively, via the bit lines BL. During a read operation, the page buffers may sense a current or voltage across the bit lines which varies according to the threshold voltages of the selected memory cells in response to page buffer control signals PBSIG, and they may temporarily store the sensed data.

The column decoder 150 may transfer data between the page buffer group 140 and the input/output circuit 160 in response to a column address CADD. For example, the column decoder 150 may be coupled to the page buffer group 140 via column lines CL, and it may transfer enable signals via the column lines CL. In response to the enable signals, the page buffers (not shown) included in the page buffer group 140 may receive or output data via data lines DL.

The input/output circuit 160 may receive or output a command CMD, an address ADD, or data via input/output lines I/O. For example, the input/output circuit 160 may transfer the command CMD and the address ADD received from an external controller to the control circuit 180 via the input/output lines I/O, and it may transfer data received from the external controller to the page buffer group 140 via the input/output lines I/O. Alternatively, the input/output circuit 160 may output data received from the page buffer group 140 to the external controller via the input/output lines I/O.

The control circuit 180 may output at least one of the operation code OPCD, the row address RADD, the page buffer control signals PBSIG, or the column address CADD in response to the command CMD and the address ADD. For example, when the command CMD input to the control circuit 180 corresponds to a program operation, the control circuit 180 may control the peripheral circuit 170 such that the program operation of the memory block selected by the address ADD is performed. When the command CMD input to the control circuit 180 corresponds to a read operation, the control circuit 180 may control the peripheral circuit 170 to perform the read operation of the memory block selected by the address and to output the read data. When the command CMD input to the control circuit 180 corresponds to an erase operation, the control circuit 180 may control the peripheral circuit 170 to perform the erase operation of the selected memory block.

FIG. 2 is a diagram illustrating the memory device 100 according to an embodiment of the present disclosure.

Referring to FIG. 2, the memory device 100 may include a peripheral circuit structure PC and the first to ith memory blocks BLK1 to BLKi disposed on a substrate SUB. The first to ith memory blocks BLK1 to BLKi may overlap with the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or a selective epitaxial thin layer formed via a selective epitaxial growth method.

The peripheral circuit structure PC may include the row decoder 130, the column decoder 150, the page buffer group 140, and the control circuit 180 which constitute circuitry for controlling the operations of the first to ith memory blocks BLK1 to BLKi. For example, the peripheral circuit structure PC may include NMOS transistors, PMOS transistors, resistors, and capacitors electrically coupled to the first to ith memory blocks BLK1 to BLKi. The peripheral circuit structure PC may be disposed between the substrate SUB and the first to ith memory blocks BLK1 to BLKi.

Each of the first to ith memory blocks BLK1 to BLKi may include a source structure, bit lines, cell strings electrically coupled to the source structure and the bit lines, word lines electrically coupled to the cell strings, and selected word lines electrically coupled to the cell strings. Each of the cell strings may include memory cells and select transistors coupled in series by cell plugs. Each of the select lines may serve as a gate electrode of a corresponding select transistor, and each of the word lines may serve as a gate electrode of a corresponding memory cell.

In another embodiment, the substrate SUB, the peripheral circuit structure PC, and the first to ith memory blocks BLK1 to BLKi may be stacked in a reverse order to the order as shown in FIG. 2. For example, the peripheral circuit structure PC may be disposed on top of the first to ith memory blocks BLK1 to BLKi.

In another embodiment, unlike the embodiment shown in FIG. 2, the peripheral circuit structure PC may be disposed on a portion of the substrate SUB which does not overlap with the first to ith memory blocks BLK1 to BLKi. For example, the peripheral circuit structure PC and the first to ith memory blocks BLK1 to BLKi may be disposed on different regions of the substrate SUB.

FIGS. 3A to 3C are diagrams illustrating a memory device including support structures according to an embodiment of the present disclosure. FIG. 3B is a cross-sectional view corresponding to a cross-section A-A′ of FIG. 3A. FIG. 3C is a perspective view illustrating one of cell plugs CPL and one of support structures SS of FIG. 3B.

Referring to FIG. 3A, the memory device 100 may include a cell region CR and a contact region CTR. The contact region CTR may be located in an X direction from the cell region CR. The contact region CTR may extend in the X direction from the cell region CR. Unlike in FIG. 3A, the contact region CTR may extend in a Y direction from the cell region CR, or it may extend in both the X and Y directions. In addition, the cell region CR and the contact region CTR may be arranged in various ways.

The cell plugs CPL may be located in the cell region CR. The cell plugs CPL may be arranged along the X and Y directions. The cell plugs CPL may be spaced apart from each other in the X and Y directions. Each of the cell plugs CPL may extend in a Z direction. Each of the cell plugs CPL may be electrically coupled to a bit line (e.g., a bit line BL in FIG. 1) and a source line (e.g., the source line SL in FIG. 1) via a wiring structure.

Each of the cell plugs CPL may include a memory layer ML, a channel layer CH, and a core pillar CO. The memory layer ML may have a cylindrical shape. The memory layer ML may surround the periphery of the channel layer CH. The memory layer ML may include a blocking layer BX, a charge trap layer CTL, and a tunneling layer TX. The channel layer CH may be formed along an inner wall of the memory layer ML. The core pillar CO may fill an inside of the channel layer CH. The core pillar CO may have a cylindrical shape and be surrounded by the channel layer CH.

The blocking layer BX and the tunneling layer TX may include an oxide layer (e.g., a silicon oxide layer), an oxynitride layer (e.g., a silicon oxynitride layer), or a combination thereof. The charge trap layer CTL may include a nitride layer or a variable resistance material. The channel layer CH may include an undoped or doped silicon layer. The core pillar CO may include an insulating layer (e.g., an oxide layer).

Contacts CT may be located in the contact region CTR. A plurality of contacts may be disposed within the contact region CTR, and only some of the contacts CT are shown in FIG. 3A. The contacts CT may extend in the Z direction. The contacts CT may include a conductive material. The contacts CT may also be referred to as contact plugs.

Spacers SP may surround side surfaces of the contacts CT, respectively. The contacts CT may fill the insides of the spacers SP, respectively. The spacers SP may include an insulating layer. For example, the spacers SP may include an oxide layer.

The support structures SS may be located in the contact region CTR. The support structures SS may be spaced apart from each other. The support structures SS may include an insulating material. The support structures SS may be disposed around the periphery of the contacts CT. Each of the contacts CT may be arranged to be surrounded by support structures SS. However, the arrangement of the support structures SS and the contacts CT as shown in FIG. 3A is an example, and various other embodiments are possible. For example, there may be five or fewer or seven or more support structures SS neighboring each of the contacts CT.

Referring to FIG. 3B, the memory device 100 may include a stack STK. The stack STK may include conductive layers CD and interlayer insulating layers IL. The conductive layers CD and the interlayer insulating layers IL may be alternately stacked in the Z direction. The conductive layers CD may include at least one of tungsten (W), cobalt (Co), nickel (Ni), molybdenum (Mo), silicon (Si), or polysilicon (poly-Si). The conductive layers CD may correspond to gate lines (e.g., the drain select lines DSL, the word lines WL, and the source select lines SSL of FIG. 1). The interlayer insulating layers IL may include an oxide layer (e.g., a silicon oxide layer).

The cell plugs CPL may extend through the stack STK in the cell region CR of the stack STK. Each of the cell plugs CPL may include the memory layer ML, the channel layer CH, a capping layer CAP, and the core pillar CO. The capping layer CAP may be in contact with the channel layer CH. The capping layer CAP may be located on the core pillar CO. Memory cells and select transistors may be formed at intersections of the cell plug CPL and the conductive layers CD, respectively. The cell plugs CPL may serve as a channel region of the cell string.

The contacts CT may extend in the Z direction within the contact region CTR of the stack STK. Each contact CT may be in contact with one of the conductive layers CD. For example, a contact CT may extend in the Z direction from a first conductive layer CD1 of the conductive layers CD included in the stack STK. A lower surface of the contact CT may contact a portion of an upper surface of the first conductive layer CD1. The contact CT may be electrically coupled to the first conductive layer CD1.

According to the present disclosure, the stack STK might not be formed in a stepped structure. For example, within the contact region CTR, the stack STK might not be stepped. Therefore, the contact CT may penetrate a portion of the stack STK. For example, the contact CT may penetrate a second conductive layer CD2 located on top of the first conductive layer CD1. The contact CT may be electrically isolated from the second conductive layer CD2.

The spacer SP may surround a side surface of the contact CT. The spacer SP may be positioned between the contact CT and the stack STK. The spacer SP may isolate the contact CT from other conductive layers CD other than the first conductive layer CD1. For example, the spacer SP may isolate the contact CT from the conductive layers CD (e.g., the second conductive layer CD2) located over the first conductive layer CD1.

The support structures SS may penetrate the contact region CTR of the stack STK. The support structures SS may penetrate the conductive layers CD and the interlayer insulating layers IL. The support structures SS may extend in the Z direction.

Each of the support structures SS may include a first portion P1 and a second portion P2. The second portion P2 may be arranged under the first portion P1. The first portion P1 may be disposed in the Z direction from the second portion P2. The first portion P1 may penetrate an upper portion of the stack STK, and the second portion P2 may penetrate a lower portion of the stack STK.

Referring to FIGS. 3B and 3C together, a width WS2 of the second portion P2 of the support structure SS may be larger than a width WS1 of the first portion P1. For example, at the interface of the first portion P1 and the second portion P2, the width WS1 of the first portion P1 may be less than the width WS2 of the second portion P2. As the distance from the interface of the first portion P1 and the second portion P2 increases, the width WS2 of the second portion P2 may have a value closer to the width WS1 of the first portion P1. In another example, the minimum width of the second portion P2 may be greater than the maximum width of the first portion P1. In another example, the second portion P2 may have a larger width than an extension line of the first portion P1 (e.g., the dashed line in FIG. 3C).

At a first level LV1, the width WS1 of the first portion P1 of the support structure SS may be substantially the same as a width WC1 of the cell plug CPL. At a second level LV2, which is located lower than the first level LV1, the width WS2 of the second portion P2 of the support structure SS may be greater than a width WC2 of the cell plug CPL.

A side surface of the second portion P2 may protrude more toward the stack STK than a side surface of the first portion P1. Some of an upper surface of the second portion P2 may overlap with the first portion P1 and other portions thereof might not overlap with the first portion P1. For example, some of the upper surface of the second portion P2 may be in contact with a lower surface of the first portion P1 and other portions of the upper surface of the second portion P2 may be in contact with the interlayer insulating layer IL (or the conductive layer CD). Referring to FIG. 3B, the side surfaces of the support structures SS may include grooves GR. In an embodiment, the groove represents a shoulder or shelf where the width WS2 of the second portion P2 is wider than the width WS1 of the first portion P1 where the second portion P2 meets the first portion P1. For example, a portion of the upper surface of the second portion P2 is not overlapped by the first portion P1, resulting in the shoulder or shelf, as pictured in FIG. 3B.

Referring to FIG. 3B, the interface between the first portion P1 and the second portion P2 may be located at a different level from an interface between a conductive layer CD and an interlayer insulating layer IL. For example, the interface between the first portion P1 and the second portion P2 may be located inside one of the interlayer insulating layers IL. The groove GR formed on the side surface of the support structure SS may be located inside of one of the interlayer insulating layers IL. For example, the groove included in the side surface of the support structure SS may be surrounded by one of the interlayer insulating layers IL.

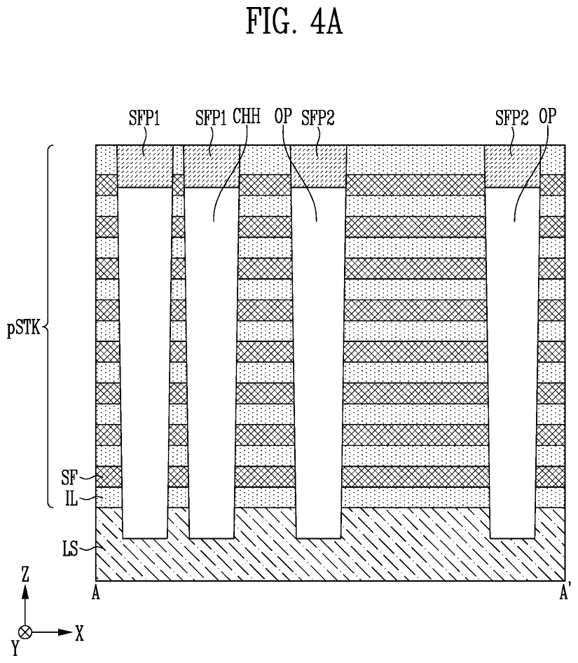

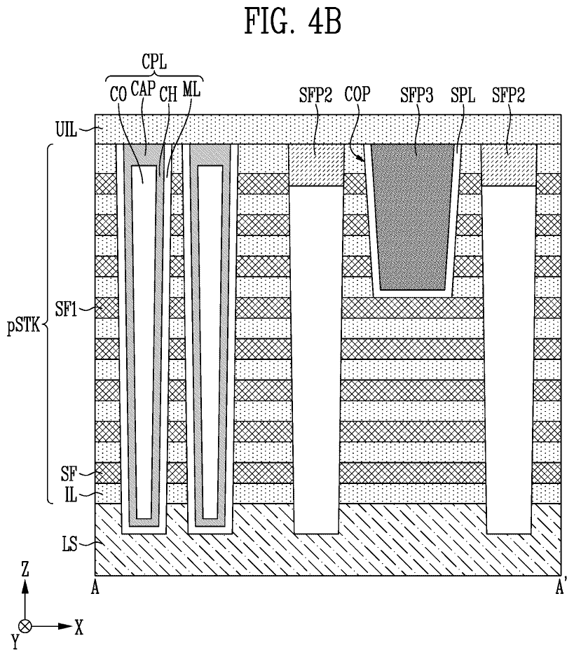

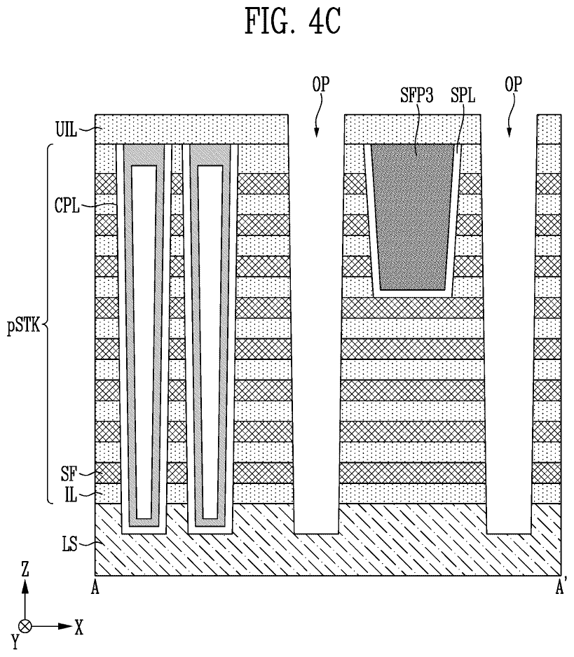

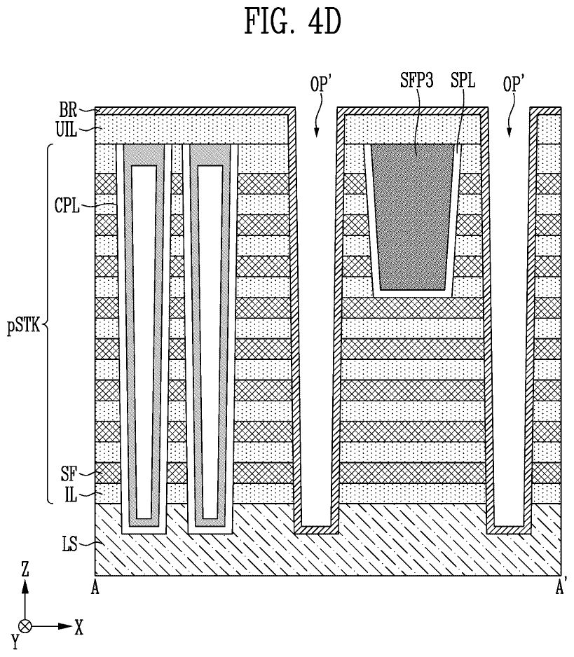

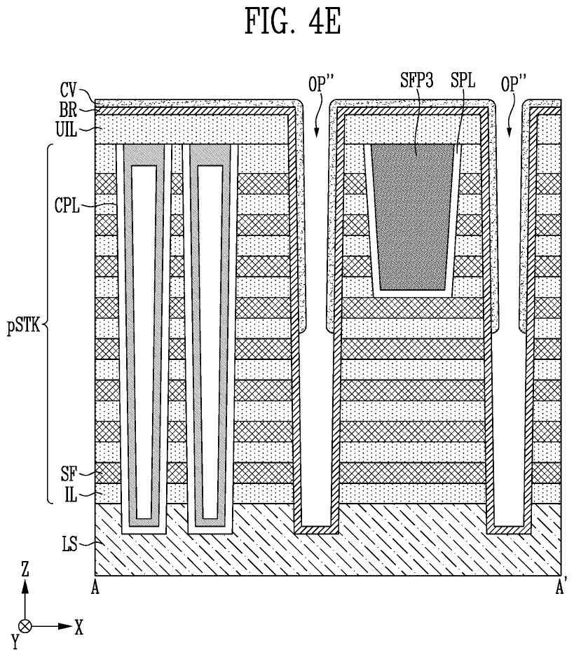

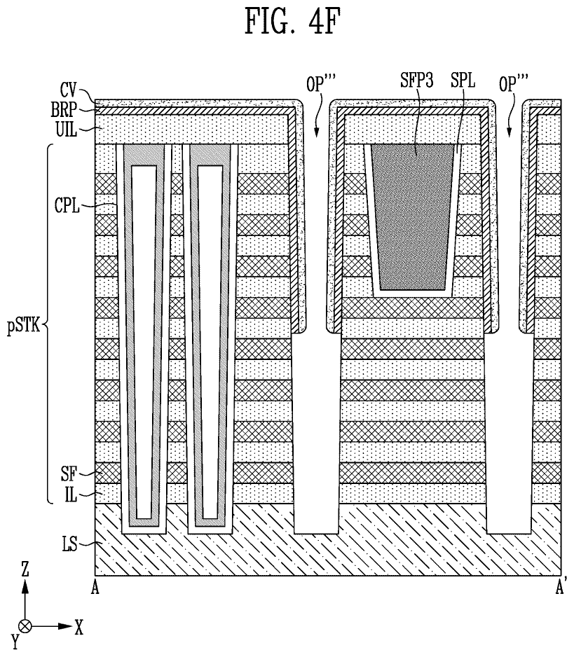

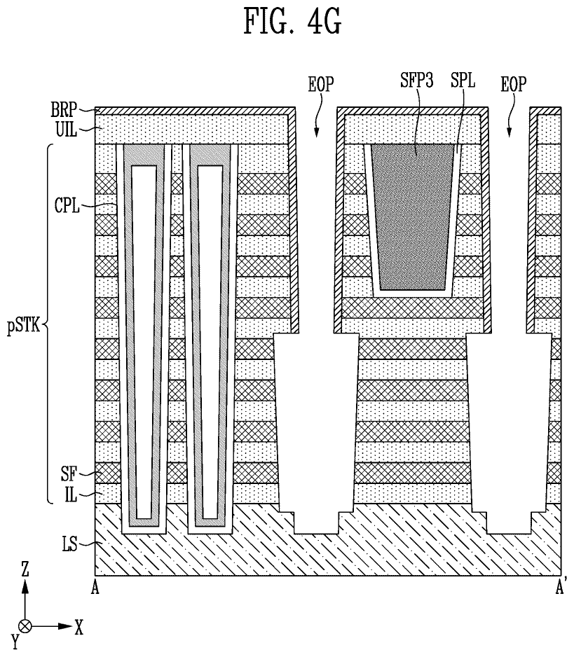

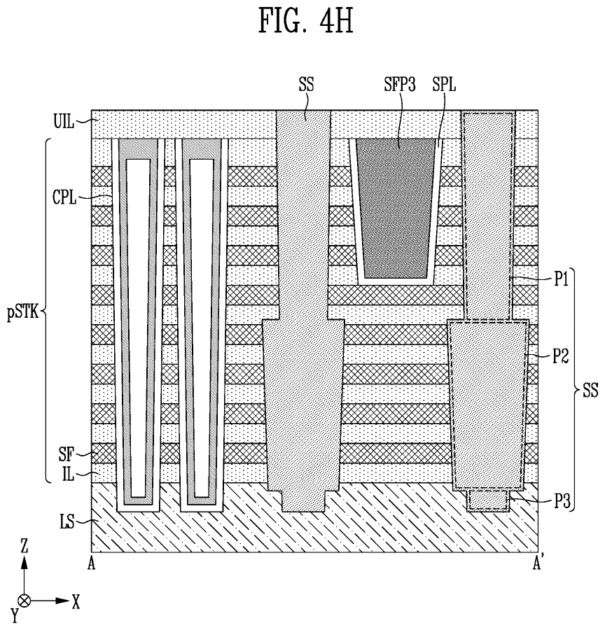

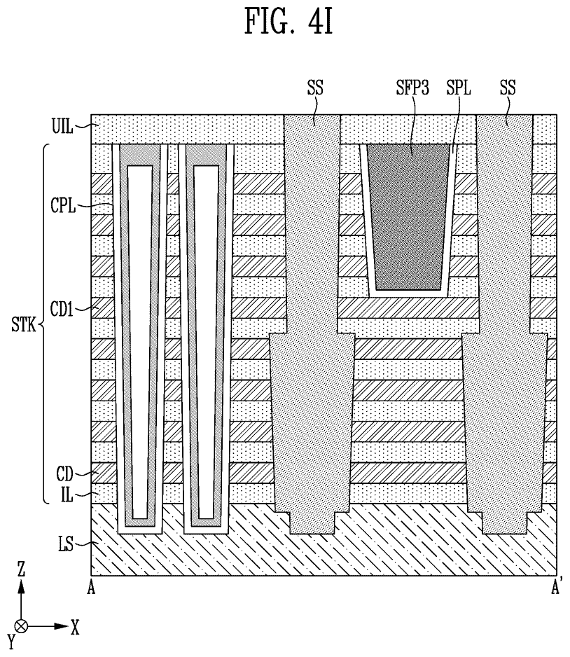

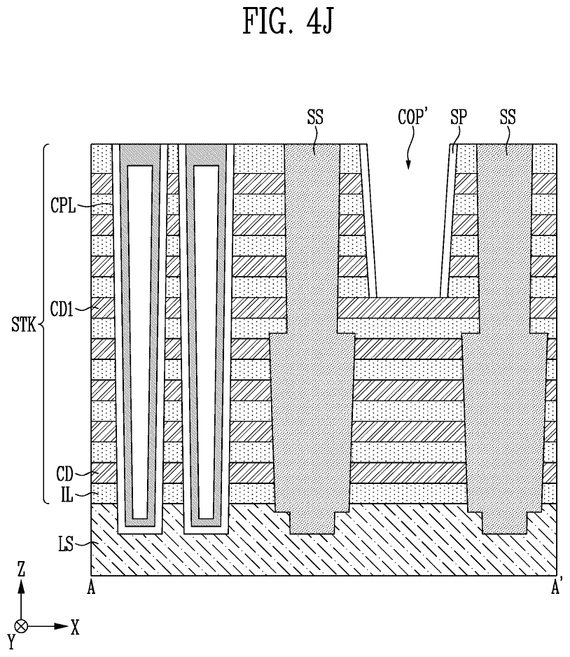

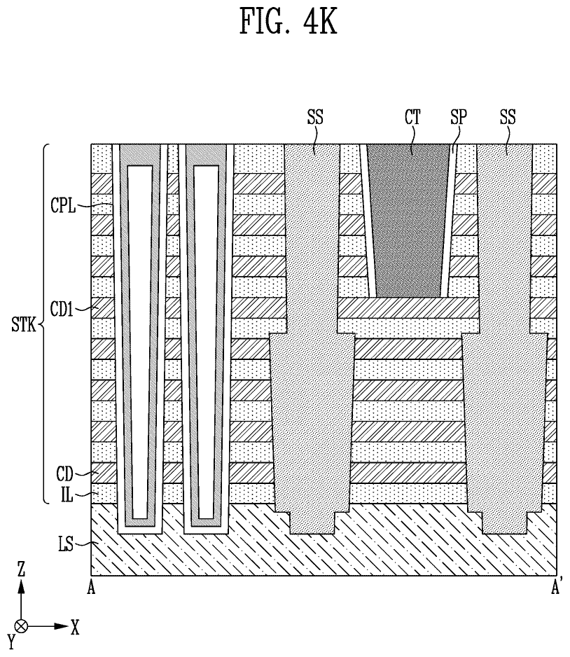

FIGS. 4A to 4K are diagrams illustrating a method of manufacturing a memory device including a support structure according to an embodiment of the present disclosure. FIGS. 4A to 4K illustrate cross-sections corresponding to a cross-section A-A′ of FIG. 3A at each step during manufacturing processes of the memory device 100.

Referring to FIG. 4A, a preliminary stack pSTK may be formed on a lower structure LS. The lower structure LS may include a substrate (e.g., the substrate SUB of FIG. 2). The preliminary stack pSTK may include the interlayer insulating layers IL and sacrificial layers SF which are alternately stacked on each other. The interlayer insulating layers IL may include an insulating material. For example, the interlayer insulating layers IL may include an oxide layer (e.g., a silicon oxide layer). The sacrificial layers SF may include a material which is selectively removable in a subsequent process. The sacrificial layers SF may include a material having a different etch selectivity from the interlayer insulating layers IL. For example, the sacrificial layers SF may include a nitride layer.

Subsequently, channel openings CHH and openings OP may be formed through the preliminary stack pSTK. The channel openings CHH may penetrate the cell region CR of the preliminary stack pSTK. The channel openings OP may penetrate the contact region CTR of the preliminary stack pSTK. The channel openings CHH and the openings OP may expose the side surface of the preliminary stack pSTK. The channel openings CHH and the openings OP may extend into the lower structure LS. The channel openings CHH and the openings OP may expose a portion of the lower structure LS. The channel openings CHH and the openings OP may have a cylindrical shape. For example, the channel openings CHH and the openings OP may have a circular or elliptical planar shape.

The channel openings CHH and the openings OP may be formed simultaneously. For example, the channel openings CHH and the openings OP might not be formed in separate etch processes, but they may instead be formed together in one etch process. During a process in which openings with a high aspect ratio are etched simultaneously, the openings OP may be formed simultaneously with the channel openings CHH. By simultaneously etching the openings with the high aspect ratio, the cost and time required for the etching process may be reduced for some embodiments. An anisotropic dry etch process may be performed to form the channel openings CHH and the openings OP at specific locations.

In one embodiment, the channel openings CHH and the openings OP may have the same planar area. In another embodiment, the channel openings CHH and the openings OP may have different planar areas.

Subsequently, first and second sacrificial patterns SFP1 and SFP2 may be formed in the channel openings CHH and the openings OP. Each of the first sacrificial patterns SFP1 may fill at least a portion of a channel opening CHH. Each of the second sacrificial patterns SFP2 may fill at least a portion of an opening OP. For example, the first sacrificial patterns SFP1 may be located on top of the channel openings CHH. The second sacrificial patterns SFP2 may be located at the top of the openings OP. The first and second sacrificial patterns SFP1 and SFP2 may include a carbon layer. For example, the first and second sacrificial patterns SFP1 and SFP2 may include a carbon layer, a carbon layer and polysilicon, or a carbon layer and a metal nitride (e.g., TiN).

Referring to FIG. 4B, the first sacrificial patterns SFP1 may be removed from the channel openings CHH. Subsequently, the cell plugs CPL may be formed within the channel openings CHH. For example, the memory layer ML, the channel layer CH, and the core pillar CO may be formed sequentially along an inner surface of each of the channel openings CHH. In addition, the capping layer CAP in contact with an inner surface of the channel layer CH and an upper surface of the core pillar CO may be formed.

Subsequently, a contact opening COP may be formed in the contact region CTR of the preliminary stack pSTK. The contact opening COP may be spaced apart from the openings OP. The contact opening COP may expose a first sacrificial layer SF1 of the sacrificial layers SF. The contact opening COP may extend in the Z direction from the first sacrificial layer SF. The contact opening COP may expose an upper surface of the first sacrificial layer SF1.

To form the contact opening COP, processes may be performed to alternately remove the interlayer insulating layers IL and the sacrificial layers SF. Processes may be performed to sequentially etch oxide and nitride layers so that the contact opening COP may be formed to a specific depth (e.g., a depth corresponding to the first sacrificial layer SF1). Because the etching processes are performed in multiple steps, the planar area of the contact opening COP may be greater than that of each of the channel openings CHH or the openings OP.

Subsequently, a spacer layer SPL may be formed along an inner surface of the contact opening COP. The spacer layer SPL may extend along side and bottom surfaces of the contact opening COP. The spacer layer SPL may be formed on side and top surfaces of the preliminary stack pSTK exposed through the contact opening COP. The spacer layer SPL may be conformally formed along the side surface of the preliminary stack pSTK. The spacer layer SPL may include an insulating material. For example, the spacer layer SPL may include an oxide layer.

Subsequently, a third sacrificial pattern SFP3 may be formed to fill the inside of the contact opening COP. The third sacrificial pattern SFP3 may fill the inside of the spacer layer SPL. The third sacrificial pattern SFP3 may be surrounded by the spacer layer SPL. The third sacrificial pattern SFP3 may be separated from the preliminary stack pSTK by the spacer layer SPL. The third sacrificial pattern SFP3 may include at least one of a carbon layer or polysilicon.

Subsequently, an upper insulating layer UIL may be stacked on top of the interlayer insulating layers IL and the sacrificial patterns SF. The upper insulating layer UIL may cover the cell plugs CPL and the second and third sacrificial patterns SFP2 and SFP3. The upper insulating layer UIL may include the same material as the interlayer insulating layers IL.

Referring to FIG. 4C, a portion of the upper insulating layer UIL may be etched to expose the second sacrificial patterns SFP2. Subsequently, the second sacrificial patterns SFP2 may be removed. As the second sacrificial patterns SFP2 are removed, the openings OP may be uncovered and re-opened.

Referring to FIG. 4D, a barrier layer BR may be formed along inner surfaces of the openings OP. The barrier layer BR may extend along the side and bottom surfaces of the openings OP. The barrier layer BR may be formed on the side surface of the preliminary stack pSTK exposed through the openings OP. The barrier layer BR may extend over the upper surface of the preliminary stack pSTK. The barrier layer BR may be formed conformably along the side and top surfaces of the preliminary stack pSTK. The barrier layer BR may be formed on the surface of the lower structure LS which is exposed through the openings OP. The preliminary stack pSTK and the lower structure LS might no longer be exposed through the resulting openings OP′ after the barrier layer BR is formed. The barrier layer BR may include metal or metal nitride (e.g., TiN).

Referring to FIG. 4E, a cover layer CV in contact with a portion of the barrier layer BR may be formed. The cover layer CV may be in contact with an upper portion of the barrier layer BR and might not be in contact with a lower portion of the barrier layer BR. The cover layer CV may extend along the upper surface of the preliminary stack pSTK. The cover layer CV may extend along a side surface of the barrier layer BR formed within the openings OP′. A portion (e.g., the lower portion) of the barrier layer BR may be left exposed through resulting openings OP″ after the cover layer CV is formed. The cover layer CV may include an insulating material. For example, the cover layer CV may include an oxide layer (e.g., ultra-low temperature oxide (ULTO)).

In an embodiment, the cover layer CV may be formed at a depth which is in contact with a portion (e.g., the upper portion) of the barrier layer BR. For example, the step coverage of the cover layer CV may be adjusted such that the cover layer CV may be deposited only to a specified depth of the opening OP′ and not below the depth.

In another embodiment, a material layer covering the barrier layer BR may be formed, and a portion of the material layer may be removed to form the cover layer CV. For example, the cover layer CV may be formed by a process of selectively etching a lower portion of the material layer in contact with the barrier layer BR.

The depth of the cover layer CV may be determined independently of the position of the sacrificial layers SF or the position of the interlayer insulating layers IL. A level of a lower portion of the cover layer CV may be different from levels of the interfaces between the sacrificial layers SF and the interlayer insulating layers IL. For example, the Z-direction position of the lower portion of the cover layer CV may correspond to one of the interlayer insulating layers IL.

Referring to FIG. 4F, a portion of the barrier layer BR may be removed to form a barrier pattern BRP. Areas of the barrier layer BR which are not covered by the cover layer CV may be etched. For example, a portion of the barrier layer BR which is lower than the cover layer CV may be removed. The lower portion of the barrier layer BR may be etched using the cover layer CV as an etch barrier. A portion of the side surface of the preliminary stack pSTK may be exposed below the barrier pattern BRP. A lower portion of the side surface of the preliminary stack pSTK may be exposed through resulting openings OP′″ after the barrier pattern BRP is formed.

Referring to FIG. 4G, a portion of the preliminary stack pSTK may be etched through the exposed side surface of the preliminary stack pSTK. While the portion of the preliminary stack pSTK is being etched, the cover layer CV may also be removed. When the portion of the preliminary stack pSTK is etched, the lower structure LS might not be etched or may be etched less than the preliminary stack pSTK. As the portion of the preliminary stack pSTK is etched, the openings OP′″ may expand to form expanded openings EOP.

Each of the expanded openings EOP may selectively have an expanded width in a middle portion compared to the openings OP of FIG. 4A. The middle portion of each of the expanded openings EOP may have an expanded width compared to the middle portion of each of the openings OP of FIG. 4A. In FIG. 4G, the middle portion of the expanded opening EOP may refer to a region corresponding to the lower portion of the preliminary stack pSTK. An upper portion of the expanded opening EOP might not be expanded in width compared to the upper portion of the opening OP of FIG. 4A. A lower portion of each of the expanded openings EOP might not extend in width relative to the lower portion of each of the openings OP of FIG. 4A. In FIG. 4G, the lower portion of the expanded opening EOP may refer to a region corresponding to the lower structure LS.

Referring to FIG. 4H, the barrier pattern BRP may be removed. Subsequently, the support structures SS may be formed within the expanded openings EOP. For example, the support structures SS may be formed by filling the expanded openings EOP with an insulating material.

Each of the support structures SS may include the first portion P1, the second portion P2, and a third portion P3. The first portion P1 may be located in the Z direction from the second and third portions P2 and P3. The second portion P2 may be located between the first and third portions P1 and P3. The third portion P3 may be located under the first and second portions P1 and P2. The second portion P2 may have a greater width than the first and third portions P1 and P3. The first portion P1 may have an equal or greater width compared to the third portion P3. The third portion P3 may be located inside the lower structure LS. The second portion P2 may penetrate the lower portion of the preliminary stack pSTK. The first portion P1 may penetrate an upper portion of the preliminary stack pSTK.

Referring to FIG. 4I, the sacrificial layers SF of the preliminary stack pSTK may be removed. The sacrificial layers SF may be etched through a slit (not shown) which is formed through the preliminary stack pSTK. As the sacrificial layers SF are removed, empty spaces may be formed between the interlayer insulating layers IL. According to the present disclosure, because the support structures SS support the interlayer insulating layers IL spaced apart from each other, bending of the interlayer insulating layers IL may be reduced. In particular, as the planar area of the contact opening COP increases, the risk of bending of the interlayer insulating layers IL located under the contact opening COP increases. However, according to the present disclosure, the support performance of the support structures SS may be improved because the support structures SS include the second portion P2 having a greater width than the first portion P1.

Subsequently, the conductive layers CD may be formed in the resulting spaces after the sacrificial layers SF are removed. The conductive layers CD may fill the spaces between the interlayer insulating layers IL. Thus, the sacrificial layers SF may be replaced by the conductive layers CD. For example, the first sacrificial layer SF1 of FIG. 4A may be replaced by the first conductive layer CD1.

Referring to FIG. 4J, the upper insulating layers UIL may be removed to expose the cell plugs CPL and the third sacrificial pattern SFP3. The third sacrificial pattern SFP3 inside the contact opening COP may then be removed. Subsequently, a lower surface of the spacer layer SPL may be removed to form the spacer SP. The spacer SP may extend along the inner surface of the contact opening COP. As a lower surface of the spacer layer SPL is removed, an upper surface of the first conductive layer CD1 may be exposed through a contact opening COP′.

Referring to FIG. 4K, the contact CT may be formed inside the contact opening COP′. For example, the contact CT may be formed by filling the inner surface of the contact opening COP′ with a conductive material. The contact CT may be electrically coupled to the first conductive layer CD1. The contact CT may extend in the Z direction from the first conductive layer CD1.

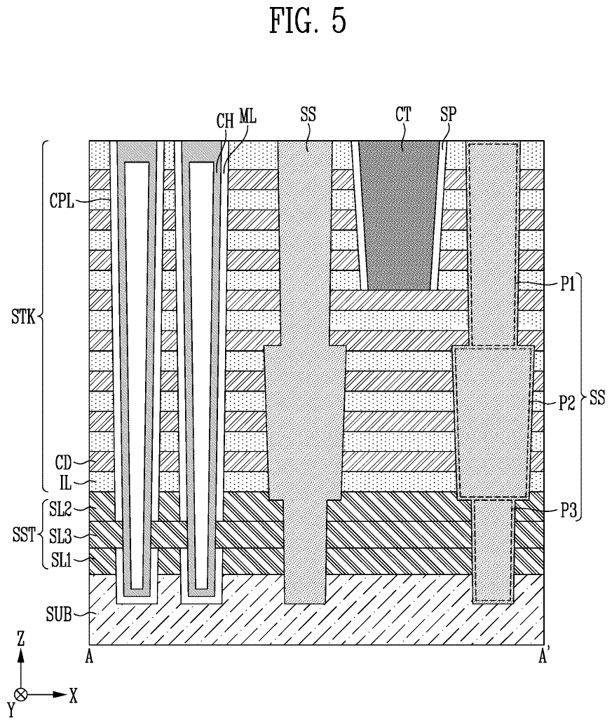

FIG. 5 is a diagram illustrating a memory device including support structures extending through a source structure, according to an embodiment of the present disclosure.

Referring to FIG. 5, the lower structure LS of FIGS. 4A to 4K may include a source structure SST and the substrate SUB. The source structure SST may include a first source layer SL1 on the substrate SUB, a second source layer SL2 between the first source layer SL1 and the stack STK, and a third source layer SL3 between the first and second source layers SL1 and SL2. The cell plugs CPL may extend through the source structure SST. The cell plugs CPL may extend into the substrate SUB. The channel layers CH may be in contact with the third source layer SL3. The third source layer SL3 may extend through the memory layers ML and be coupled to the channel layers CH.

The support structures SS may extend through the stack structure STK and the source structure SST. The support structures SS may extend into the substrate SUB. The third portions P3 of the support structures SS may extend through the source structure SST and into the substrate SUB. The second portions P2 of the support structures SS may be located on the source structure SST, or they may horizontally overlap with a portion of the source structure SST.

Referring to FIG. 5, the interface of the first portion P1 and the second portion P2 of each of the support structures SS may correspond to at least one of the conductive layers CD. For example, the interface of the first portion P1 and the second portion P2 may be located inside of one of the conductive layers CD. The upper surface of the second portion P2 may be in contact with the lower surface of the first portion P1 and may be in contact with one of the conductive layers CD. The groove included in the side surface of the support structure SS may be located on the inner surface of one of the conductive layers CD. For example, each of the grooves included in the side surface of each of the support structures SS may be surrounded by one of the conductive layers CD.

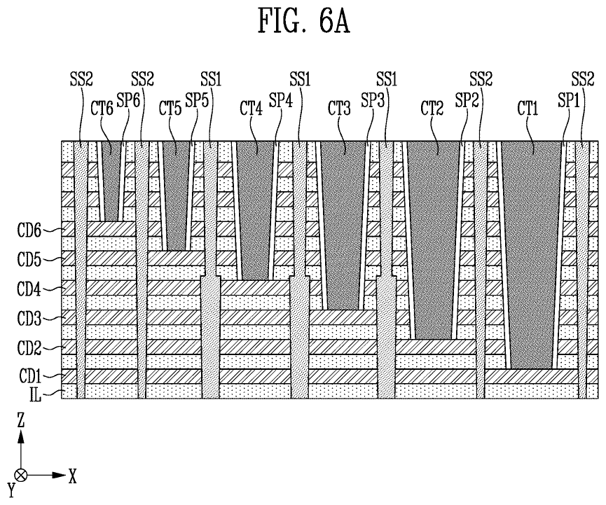

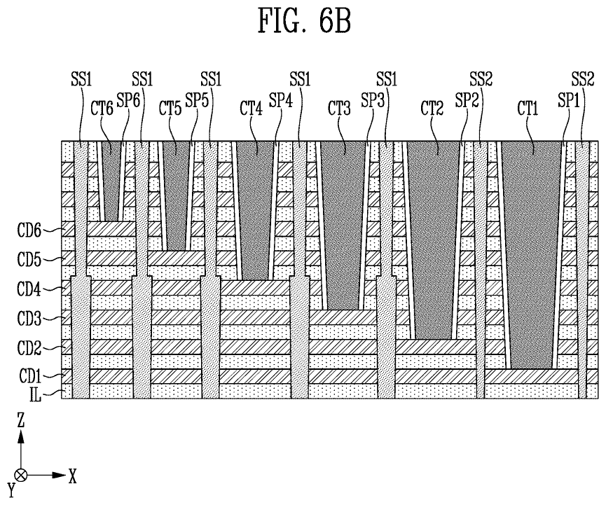

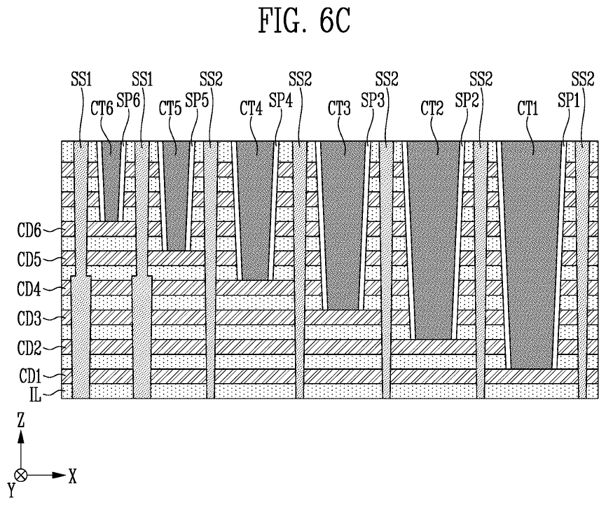

The support structure SS including the second portion P2 having a greater width than the first portion P1 is described with reference to FIGS. 3A to 3C, 4A to 4K, and 5. However, a memory device 100 according to an embodiment of the present disclosure may further include second support structures SS2 having a width which is constant or reduced toward the bottom in addition to the support structures SS including the first portion P1 and the second portion P2 (hereinafter, first support structures SS1). Referring to FIGS. 6A to 6C, a memory device 100 including the first and second support structures SS1 and SS2 is described.

FIGS. 6A to 6C are diagrams illustrating a memory device including first and second support structures according to some embodiments of the present disclosure.

Referring to FIGS. 6A to 6C, the stack STK may include first to sixth conductive layers CD1 to CD6 stacked in the Z direction. The first to sixth conductive layers CD1 to CD6 may be stacked alternately with the interlayer insulating layers IL. It may be understood that the first to sixth conductive layers CD1 to CD6 are included in the conductive layers CD of FIG. 3B.

First to sixth contacts CT1 to CT6 may extend in the Z direction within the stack STK. The first to sixth contacts CT1 to CT6 may contact the first to sixth conductive layers CD1 to CD6, respectively. It may be understood that the first to sixth contacts CT1 to CT6 are included in the contacts CT of FIGS. 3A and 3B.

The contacts CT may extend through conductive layers CD above the conductive layers CD to which the contacts CT are respectively coupled. For example, the first contact CT1 may extend through the second to sixth conductive layers CD2 to CD6. Further, the contacts CT may be formed with a greater width (e.g., a length in the X direction) as the contacts CD have a greater height (e.g., a length in the Z direction). For example, the first contact CT1 may have a greater length in the Z direction and a greater length in the X direction compared to the second to sixth contacts CT2 to CT6. Because the greater the depth of the contact opening COP for forming the contacts CT, the greater the number of sacrificial layers SF and the interlayer insulating layers IL which need to be etched, the wider the contact opening COP may be.

First to sixth spacers SP1 to SP6 may surround side surfaces of the first to sixth contacts CT1 to CT6, respectively. The first to sixth spacers SP1 to SP6 may be disposed between the first to sixth contacts CT1 to CT6 and the stack STK, respectively. The first to sixth spacers SP1 to SP6 may be insulated from the conductive layers CD other than the conductive layers CD coupled to the first to sixth contacts CT1 to CT6. For example, the first spacer SP1 may surround the side surface of the first contact CT1. The first spacer SP1 may insulate the first contact CT1 from the second to sixth conductive layers CD2 to CD6.

Referring to FIGS. 6A to 6C, the memory device 100 may include the first support structures SS1 and the second support structures SS2. The first and second support structures SS1 and SS2 may extend through the stacked stack STK. The first and second support structures SS1 and SS2 may extend through the first to sixth conductive layers CD1 to CD6.

The first support structures SS1 each may correspond to the support structures SS as described in FIGS. 3A to 3C, 4A to 4K, and 5. For example, each of the first support structures SS1 may include the first portion P1 and the second portion P2 having a greater width relative to the first portion P1. The second portion P2 may be located below the first portion P1. The first portion P1 may be located in the Z direction from the second portion P2. The interfaces of the first portions P1 and the second portions P2 included in the first support structures SS1 may be located at substantially the same level. For example, the heights of the second portions P2 included in different first support structures SS1 may be equivalent to each other.

The width of the second support structures SS2 may be constant or may be reduced towards the bottom. For example, the width of the second support structure SS2 may be substantially the same as the width of the cell plug CPL of FIG. 3C. Thus, at a first level (e.g., the first level LV1 of FIG. 3C), the width of the first portion P1 of the first support structure SS1 may be equivalent to the width of the second support structure SS2. Further, at a second level (e.g., the second level LV2 of FIG. 3C), the width of the second portion P2 of the first support structure SS1 may be greater than the width of the second support structure SS2.

Referring to FIGS. 4A to 4K together, while some of the openings OP are expanded to form the expanded openings EOP, other openings OP may be covered by the second sacrificial patterns SFP2 and might not be expanded. The first support structures SS1 may be formed within the expanded openings EOP, and the second support structures SS2 may be formed within the unexpanded openings OP.

Referring to FIGS. 6A to 6C, the side surfaces of the first support structures SS1 may include grooves. The side surfaces of the second support structures SS2 might not include the grooves. The side surfaces of the second support structure SS2, for example, may be smooth curved surfaces in the XY plane which extends straight with a taper in the Z direction.

The first and second support structures SS1 and SS2 may be disposed around the periphery of the contacts CT. In a peripheral area of the contacts CT, the first support structure SS1 may be disposed in some areas and the second support structure SS2 may be disposed in other areas. In other words, the first support structure SS1 may be disposed adjacent to a first group of the contacts CT and the second support structures SS2 may be disposed adjacent to a second group of the contacts CT. The first and second support structures SS1 and SS2 may be arranged in various manners. Referring to FIGS. 6A to 6C, the description is centered on locations where the first support structures SS1 may be disposed.

Referring to FIG. 6A, the first support structures SS1 may be disposed around the periphery of third and fourth contacts CT3 and CT4, and the second support structures SS2 may be disposed in other areas. The difference between the height of each of the third and fourth contacts CT3 and CT4 and the height of the first portion P1 of the first support structure SS1 may be less than a threshold value.

Referring to FIG. 6B, the first support structures SS1 may be disposed around the periphery of the third to sixth contacts CT3 to CT6, and the second support structures SS2 may be disposed in other areas. The height of each of the third to sixth contacts CT3 to CT6 may be less than a threshold value equal to the height of the first portion P1 of the first support structure SS1 plus a predetermined value.

Referring to FIG. 6C, the first support structures SS1 may be disposed around the periphery of the sixth contact CT6, and the second support structures SS2 may be disposed in other areas. The height of each of the fifth and sixth contacts CT5 and CT6 may be less than the height of the first portion P1 of the first support structures SS1.

In addition to those shown in FIGS. 6A to 6C, various other arrangements may be possible. For example, the first support structures SS1 may selectively be formed in an area where the load of the interlayer insulating layers IL at the lower portions of the contacts CT is greater than or equal to a threshold value. The area where the load of the interlayer insulating layers IL at the lower portions of the contacts CT is high may include a region where the support structures SS are spaced apart at a large distance due to the large size of the contacts CT, or a region where the length of the contacts CT is decreased such that the interlayer insulating layers IL might not be supported in the region when the sacrificial layers SF are removed.

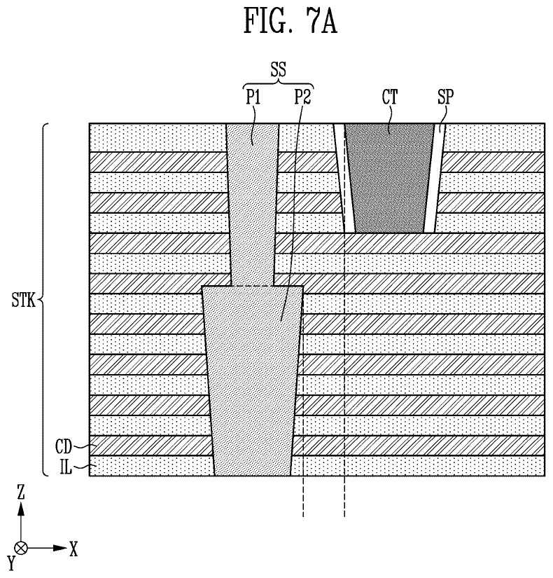

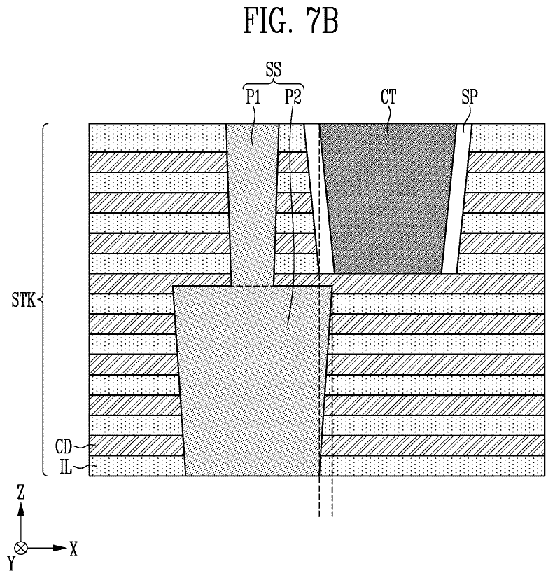

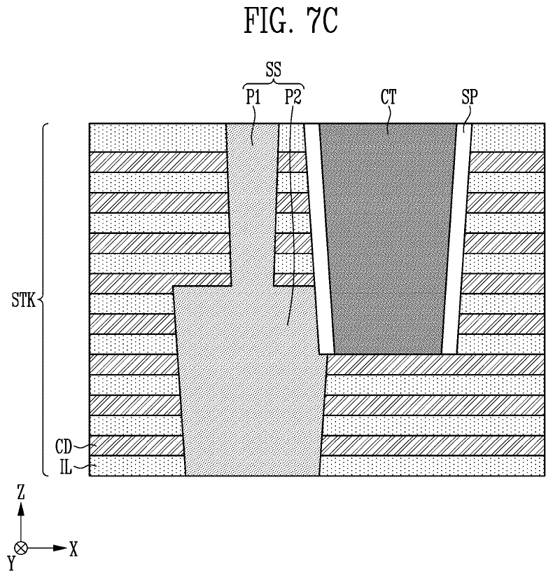

FIGS. 7A to 7C are diagrams illustrating positional relationships of the support structure and the contact according to some embodiments of the present disclosure.

FIGS. 7A to 7C illustrate various positional relationships between the support structure SS and the contact CT of FIG. 3B.

Referring to FIG. 7A, the support structure SS might not vertically overlap with the contact CT and the spacer SP.

Referring to FIG. 7B, the second portion P2 of the support structure SS may vertically overlap with the contact CT. The second portion P2 of the support structure SS may extend through the interlayer insulating layers IL located under the contact CT.

Referring to FIG. 7C, the second portion P2 of the support structure SS may vertically overlap with the contact CT and may be in contact with the spacer SP. Referring to FIG. 4G, a portion of the spacer layer SPL may be exposed while the expanded opening EOP is formed, and the support structure SS may be formed within the expanded opening EOP.

In addition to FIGS. 7A to 7C, any embodiment in which the support structures SS including the second portion P2 are formed may fall within the scope of the present disclosure.

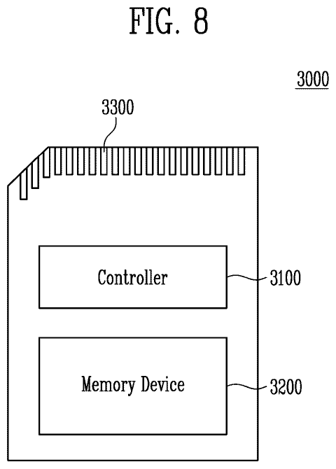

FIG. 8 is a block diagram illustrating a memory card system 3000 according to an embodiment of the present disclosure.

Referring to FIG. 8, the memory card system 3000 may include a controller 3100, a memory device 3200, and a connector 3300.

The controller 3100 may be coupled to the memory device 3200. The controller 3100 may access the memory device 3200. For example, the controller 3100 may control program, read, erase, and background operations of the memory device 3200. The controller 3100 may provide an interface between the memory device 3200 and a host. The controller 3100 may drive firmware for controlling the memory device 3200. For example, the controller 3100 may include components, such as Random-Access Memory (RAM), a processing unit, a host interface, a memory interface, and an ECC circuit.

The controller 3100 may communicate with an external device through the connector 3300. The controller 3100 may communicate with an external device (e.g., a host) based on a specific communication protocol. For example, the controller 3100 may communicate with the external device through at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) protocols. For example, the connector 3300 may be defined by at least one of the above-described various communication protocols.

The memory device 3200 may include a plurality of memory cells and be configured in the same manner as the memory device 100 as described above with reference to FIG. 1.

The controller 3100 and the memory device 3200 may be integrated into a single semiconductor device to form a memory card. For example, the controller 3100 and the memory device 3200 may be integrated into a single semiconductor device to form a memory card, such as a personal computer memory card international association (PCMCIA) card, a compact flash (CF) card, a smart media card (SM or SMC), a memory stick, a multimedia card (MMC, RS-MMC, MMCmicro, or eMMC), an SD card (SD, miniSD, microSD, or SDHC), a universal flash storage (UFS), and the like.

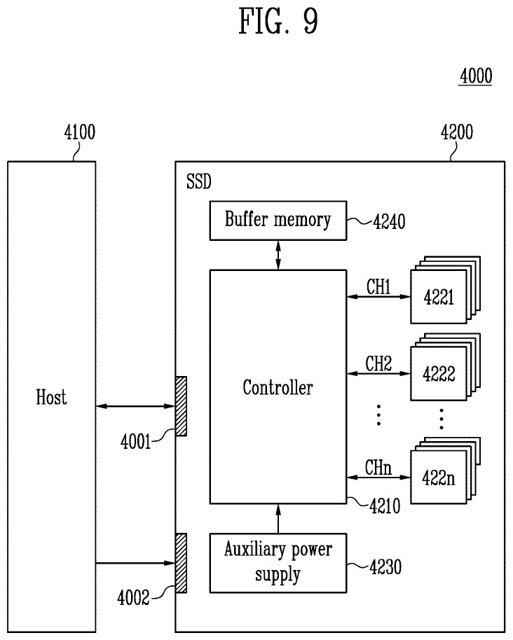

FIG. 9 is a block diagram illustrating a solid-state drive (SSD) system 4000 to which a memory device according to the present disclosure is applied.

Referring to FIG. 9, the SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of memory devices 4221 to 422n, an auxiliary power supply 4230, and buffer memory 4240.

The controller 4210 may control the plurality of memory devices 4221 to 422n in response to signals received from the host 4100. In an embodiment, the signals may be based on the interfaces of the host 4100 and the SSD 4200. For example, the signals may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), Wifi, Bluetooth, and non-volatile memory express (NVMe) interfaces.

The plurality of memory devices 4221 to 422n may include a plurality of memory cells configured to store data. Each of the plurality of memory devices 4221 to 422n may be configured in the same manner as the memory device 100 shown in FIG. 1. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied and charged with power from the host 4100. The auxiliary power supply 4230 may supply the power of the SSD 4200 when the power is not smoothly supplied from the host 4100. For example, the auxiliary power supply 4230 may be positioned inside or outside the SSD 4200. For example, the auxiliary power supply 4230 may be disposed on a main board and supply auxiliary power to the SSD 4200.

The buffer memory 4240 may serve as buffer memory for the SSD 4200. For example, the buffer memory 4240 may store data received from the host 4100 or data received from the plurality of memory devices 4221 to 422n, or it may store metadata (e.g., mapping tables) of the memory devices 4221 to 422n. The buffer memory 4240 may include volatile memory such as DRAM, SDRAM, DDR SDRAM, and LPDDR SDRAM, or non-volatile memory such as FRAM, ReRAM, STT-MRAM, and PRAM.

According to an embodiment of the present disclosure, by improving the shape of a support structure, defects such as bending or warping of stacked layers may be reduced.

It will be apparent to those skilled in the art that various modifications can be made to the above-described embodiments of the present disclosure without departing from the spirit or scope of the present teachings. Thus, it is intended that the present teachings cover all such modifications provided they come within the scope of the appended claims and their equivalents.

What is claimed is:

1. A memory device, comprising:
a stack including conductive layers and interlayer insulating layers stacked alternately with each other;
a cell plug extending through the stack;
a contact in electrical contact with at least one of the conductive layers;
a spacer between the contact and the stack; and
a support structure extending through the stack,
wherein the support structure comprises a first portion and a second portion under the first portion, the second portion having a greater width than the first portion, and
wherein an interface between the first portion and the second portion is located at a different level from interfaces between the conductive layers and the interlayer insulating layers.

2. The memory device of claim 1, wherein a portion of an upper surface of the second portion is not overlapped by the first portion.

3. The memory device of claim 1, wherein an upper surface of the second portion is in contact with a lower surface of the first portion and with at least one of the interlayer insulating layers.

4. The memory device of claim 1, wherein an upper surface of the second portion is in contact with a lower surface of the first portion and with at least one of the conductive layers.

5. The memory device of claim 1, wherein a side surface of the second portion extends laterally into the stack beyond a side surface of the first portion.

6. The memory device of claim 1, wherein a side surface of the support structure comprises a groove.

7. The memory device of claim 6, wherein the groove is located in at least one of the conductive layers or in at least one of the interlayer insulating layers.

8. The memory device of claim 1, wherein at a first level, a width of the first portion is substantially equal to a width of the cell plug, and
wherein at a second level below the first level, a width of the second portion is greater than the width of the cell plug.

9. The memory device of claim 1, further comprising a lower structure arranged under the stack,
wherein the support structure further comprises a third portion extending from the second portion into the lower structure, and
wherein a width of the third portion is less than a width of the second portion.

10. The memory device of claim 1, wherein the contact does not overlap with the support structure in a vertical direction.

11. The memory device of claim 1, wherein the contact overlaps with the second portion in a vertical direction.

12. The memory device of claim 1, wherein the contact overlaps with the second portion in a vertical direction, and
wherein the spacer is in contact with the second portion.
